(19) United States
(12) Patent Application Publication
(10) Pub. No.: US 2026/0353767 A1
(43) Pub. Date: Nov. 5, 2026

(54) SEMICONDUCTOR DEVICE

(71) Applicants: KABUSHIKI KAISHA TOSHIBA, Kawasaki-shi, Kanagawa (JP); TOSHIBA ELECTRONIC DEVICES & STORAGE CORPORATION, Kawasaki-shi, Kanagawa (JP)

(72) Inventors: Shunsuke ASABA, Himeji Hyogo (JP); Takuma SUZUKI, Himeji Hyogo (JP); Hiroshi KONO, Himeji Hyogo (JP)

(73) Assignees: KABUSHIKI KAISHA TOSHIBA, Kawasaki-shi, Kanagawa (JP); TOSHIBA ELECTRONIC DEVICES & STORAGE CORPORATION, Kawasaki-shi, Kanagawa (JP)

(21) Appl. No.: 19/485,706

(22) PCT Filed: Apr. 1, 2024
(86) PCT No.: PCT/JP2024/013495

§ 371 Date: Nov. 19, 2025

(30) Foreign Application Priority Data
Sep. 22, 2023 (JP) 2023-158095

(51) Int. Cl. H10D 84/00; H10D 62/10; H10D 62/832

(52) U.S. Cl. CPC H10D 84/146; H10D 62/109; H10D 62/127; H10D 62/8325

(57) ABSTRACT

There are included: a silicon carbide layer having a first face and a second face and including a first silicon carbide region of a first conductive type, a second silicon carbide region of a second conductive type, and a third silicon carbide region of a first conductive type; a first gate electrode and a second gate electrode extending in a first direction; a first electrode on the first face side including a first portion in contact with the second silicon carbide region and the third silicon carbide region between the first gate electrode and the second gate electrode and a second portion in contact with the first silicon carbide region between the first gate electrode and the second gate electrode and provided in the first direction of the first portion; and a second electrode on the second face side. The distribution of a first conductive type impurity concentration of the third silicon carbide region in a direction from the first face to the second face has a plurality of inflection points on the first face side of a first position where the distribution indicates a maximum impurity concentration when the first conductive type impurity concentration is expressed on a logarithmic scale.

### TECHNICAL FIELD

Embodiments of the present invention relate to a semiconductor device.

### BACKGROUND ART

Silicon carbide is a material for semiconductor devices. Silicon carbide has excellent physical properties, such as a bandgap of about 3 times that of silicon, a breakdown field strength of about 10 times that of silicon, and a thermal conductivity of about 3 times that of silicon. By using such characteristics, it is possible to realize a metal oxide semiconductor field effect transistor (MOSFET) that has a high breakdown voltage and low loss and that can operate at high temperature, for example.

A vertical MOSFET using silicon carbide has a pn junction diode as a built-in diode. For example, a MOSFET is used as a switching element connected to an inductive load. In this case, even when the MOSFET is in an off state, a freewheeling current can be made to flow by using a pn junction diode.

However, when a freewheeling current is made to flow by using a pn junction diode that operates in a bipolar manner, a stacking fault grows in a silicon carbide layer due to the recombination energy of carriers. When the stacking fault grows in the silicon carbide layer, there arises a problem that the on-resistance of the MOSFET increases. The increase in the on-resistance of the MOSFET leads to a reduction in the reliability of the MOSFET. For example, by providing a Schottky barrier diode (SBD) operating in a unipolar manner in the MOSFET as a built-in diode, it is possible to suppress a stacking fault in the silicon carbide layer.

### CITATION LIST

### Patent Document

Patent Document 1: JP 2020-47680 A

### DISCLOSURE OF THE INVENTION

### Problem to be Solved by the Invention

A problem to be solved by the invention is to provide a semiconductor device that enables an increase in on-current.

### Means for Solving Problem

A semiconductor device of embodiments includes: a silicon carbide layer having a first face and a second face opposite to the first face and including a first silicon carbide region of a first conductive type having a region in contact with the first face, a second silicon carbide region of a second conductive type provided between the first silicon carbide region and the first face and extending in a first direction parallel to the first face, and a third silicon carbide region of a first conductive type provided between the second silicon carbide region and the first face, extending in the first direction, and having a first conductive type impurity concentration higher than that in the first silicon carbide region; a first gate electrode extending in the first direction and facing the second silicon carbide region and the third silicon carbide region; a second gate electrode extending in the first direction, provided in a second direction perpendicular to the first direction with respect to the first gate electrode, and facing the second silicon carbide region and the third silicon carbide region; a first gate insulating layer provided between the second silicon carbide region and the third silicon carbide region and the first gate electrode; a second gate insulating layer provided between the second silicon carbide region and the third silicon carbide region and the second gate electrode; a first electrode provided on a side of the first face of the silicon carbide layer and including a first portion provided between the first gate electrode and the second gate electrode and in contact with the second silicon carbide region and the third silicon carbide region and a second portion provided between the first gate electrode and the second gate electrode, provided in the first direction of the first portion, and in contact with the region of the first silicon carbide region; and a second electrode provided on a side of the second face of the silicon carbide layer. A distribution of a first conductive type impurity concentration of the third silicon carbide region in a direction from the first face to the second face has a plurality of inflection points on the first face side of a first position where the distribution indicates a maximum impurity concentration when the first conductive type impurity concentration is expressed on a logarithmic scale.

### BRIEF DESCRIPTION OF DRAWINGS

FIG. 1 is a schematic cross-sectional view of a semiconductor device according to a first embodiment;

FIG. 2 is a schematic top view of the semiconductor device according to the first embodiment;

FIG. 3 is an enlarged schematic cross-sectional view of the semiconductor device according to the first embodiment;

FIG. 4 is an enlarged schematic cross-sectional view of the semiconductor device according to the first embodiment;

FIG. 5 is an enlarged schematic cross-sectional view of the semiconductor device according to the first embodiment;

FIG. 6 is an enlarged schematic top view of the semiconductor device according to the first embodiment;

FIG. 7 is a diagram showing an impurity concentration distribution of the semiconductor device according to the first embodiment;

FIG. 8 is an equivalent circuit diagram of the semiconductor device according to the first embodiment;

FIG. 9 is a diagram illustrating a problem of the semiconductor device according to the first embodiment;

FIG. 10 is a diagram showing an impurity concentration distribution of a semiconductor device according to a comparative example;

FIG. 11 is a diagram showing an impurity concentration distribution of a semiconductor device according to a modification example of the first embodiment;

FIG. 12 is a diagram showing an impurity concentration distribution of a semiconductor device according to a second embodiment; and

FIG. 13 is a diagram showing an impurity concentration distribution of a semiconductor device according to a modification example of the second embodiment.

### BEST MODE(S) FOR CARRYING OUT THE INVENTION

Hereinafter, embodiments of the invention will be described with reference to the diagrams. In addition, in the following description, the same or similar members and the like may be denoted by the same reference numerals, and the description of the members and the like once described may be omitted as appropriate.

In addition, in the following description, when there are notations of n⁺, n, n⁻, p⁺, p, and p⁻, these notations indicate the relative high and low of the impurity concentration in each conductive type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

The impurity concentration can be measured by, for example, secondary ion mass spectrometry (SIMS). In addition, the relative high and low of the impurity concentration can be determined from, for example, the high and low of the carrier concentration obtained by scanning capacitance microscopy (SCM). In addition, the distance such as the width or depth of an impurity region can be calculated by, for example, SIMS. In addition, the distance such as the width or depth of the impurity region can be calculated from, for example, an SCM image or an image of a scanning electron microscope (SEM). In addition, the thickness and the like of the insulating layer can be measured on, for example, an image of SIMS, SEM, or a transmission electron microscope (TEM).

In addition, in this specification, the “p-type impurity concentration” of the p-type silicon carbide region means the net p-type impurity concentration obtained by subtracting the n-type impurity concentration of the region from the p-type impurity concentration of the region. In addition, the “n-type impurity concentration” of the n-type silicon carbide region means the net n-type impurity concentration obtained by subtracting the p-type impurity concentration of the region from the n-type impurity concentration of the region.

In addition, unless otherwise specified in this specification, the impurity concentration of a specific region means the maximum impurity concentration of the region.

### First Embodiment

A semiconductor device according to a first embodiment includes: a silicon carbide layer having a first face and a second face opposite to the first face and including a first silicon carbide region of a first conductive type having a region in contact with the first face, a second silicon carbide region of a second conductive type provided between the first silicon carbide region and the first face and extending in a first direction parallel to the first face, and a third silicon carbide region of a first conductive type provided between the second silicon carbide region and the first face, extending in the first direction, and having a first conductive type impurity concentration higher than that in the first silicon carbide region; a first gate electrode extending in the first direction and facing the second silicon carbide region and the third silicon carbide region; a second gate electrode extending in the first direction, provided in a second direction parallel to the first face and perpendicular to the first direction with respect to the first gate electrode, and facing the second silicon carbide region and the third silicon carbide region; a first gate insulating layer provided between the second silicon carbide region and the third silicon carbide region and the first gate electrode; a second gate insulating layer provided between the second silicon carbide region and the third silicon carbide region and the second gate electrode; a first electrode provided on a side of the first face of the silicon carbide layer and including a first portion provided between the first gate electrode and the second gate electrode and in contact with the second silicon carbide region and the third silicon carbide region and a second portion provided between the first gate electrode and the second gate electrode, provided in the first direction of the first portion, and in contact with the region of the first silicon carbide region; and a second electrode provided on a side of the second face of the silicon carbide layer. A distribution of a first conductive type impurity concentration of the third silicon carbide region in a direction from the first face to the second face has a plurality of inflection points on the first face side of a first position where the distribution indicates a maximum impurity concentration when the first conductive type impurity concentration is expressed on a logarithmic scale.

The semiconductor device according to the first embodiment is a planar gate type vertical MOSFET 100 using silicon carbide. The MOSFET 100 according to the first embodiment is, for example, a double implantation MOSFET (DIMOSFET) in which a body region and a source region are formed by ion implantation. In addition, the MOSFET 100 according to the first embodiment includes an SBD as a built-in diode.

Hereinafter, a case where the first conductive type is n-type and the second conductive type is p-type will be described as an example. The MOSFET 100 is a vertical n-channel MOSFET having electrons as carriers.

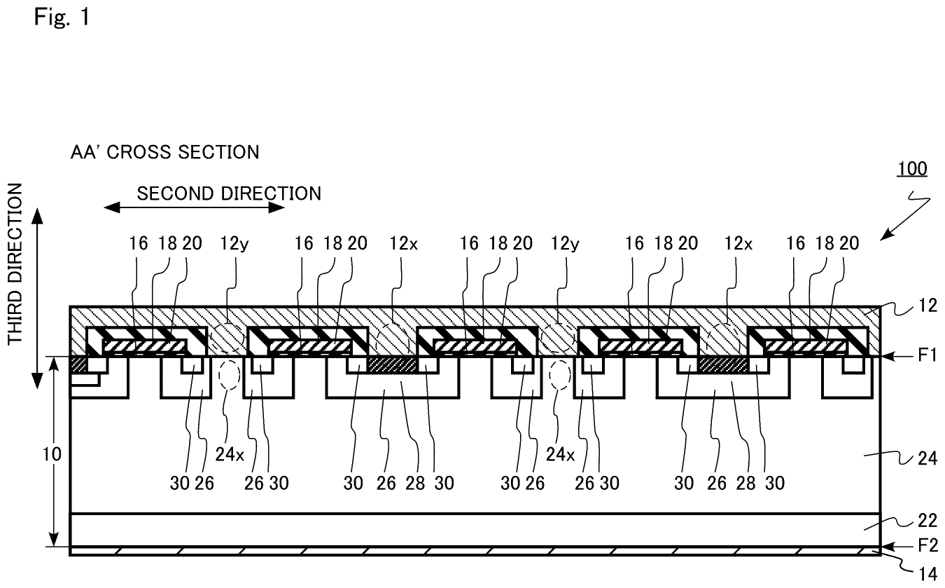

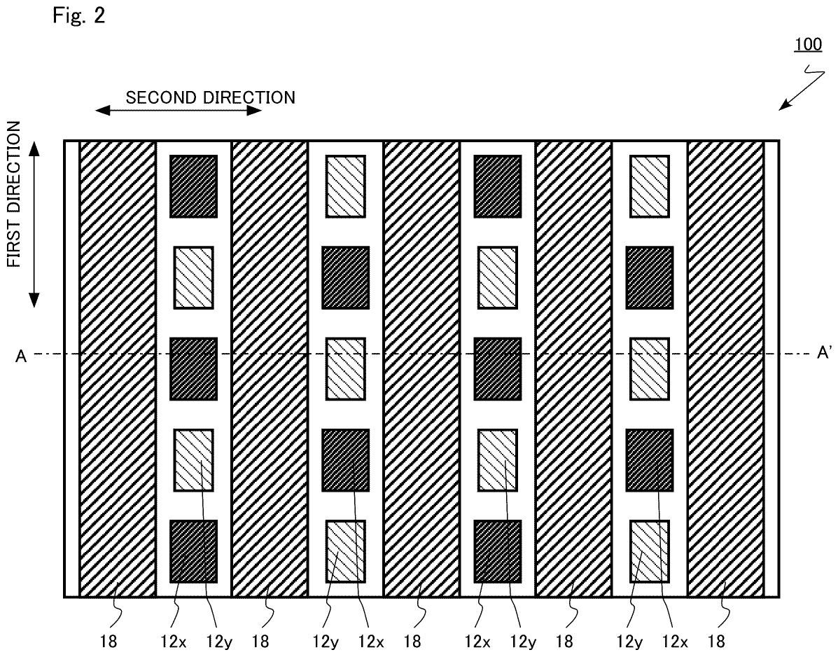

FIG. 1 is a schematic cross-sectional view of the semiconductor device according to the first embodiment. FIG. 2 is a schematic top view of the semiconductor device according to the first embodiment. FIG. 2 is a schematic diagram showing a pattern of a gate electrode and a source electrode on the top surface of a silicon carbide layer. FIG. 1 is a cross-sectional view taken along the line AA′ of FIG. 2.

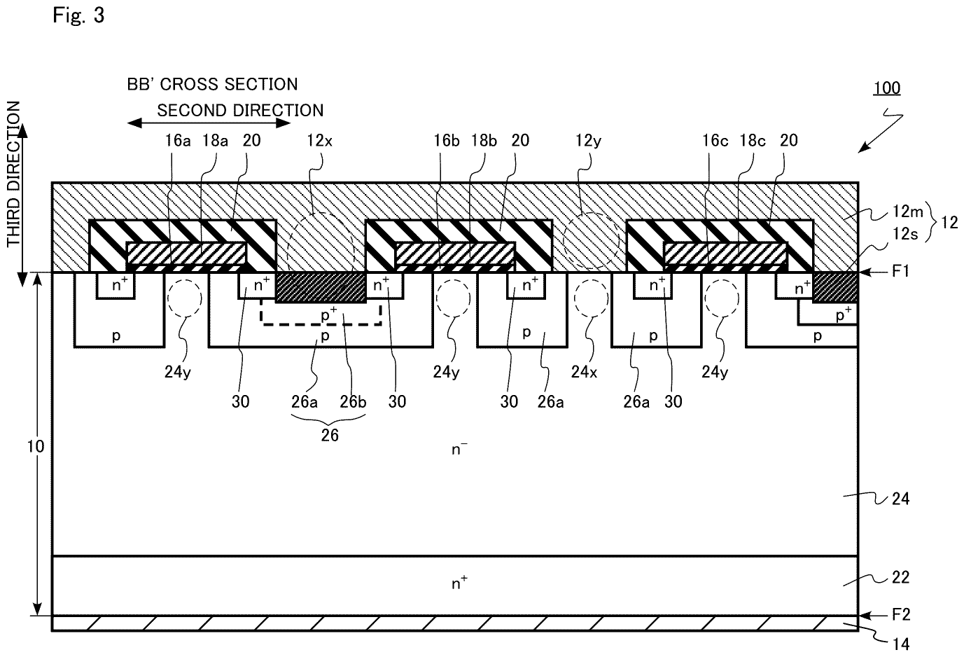

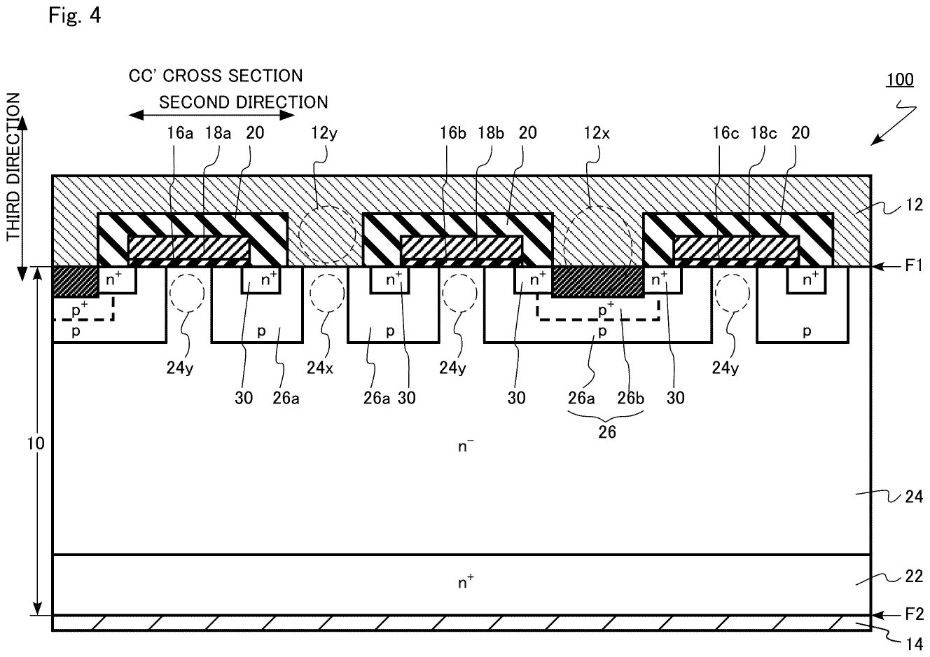

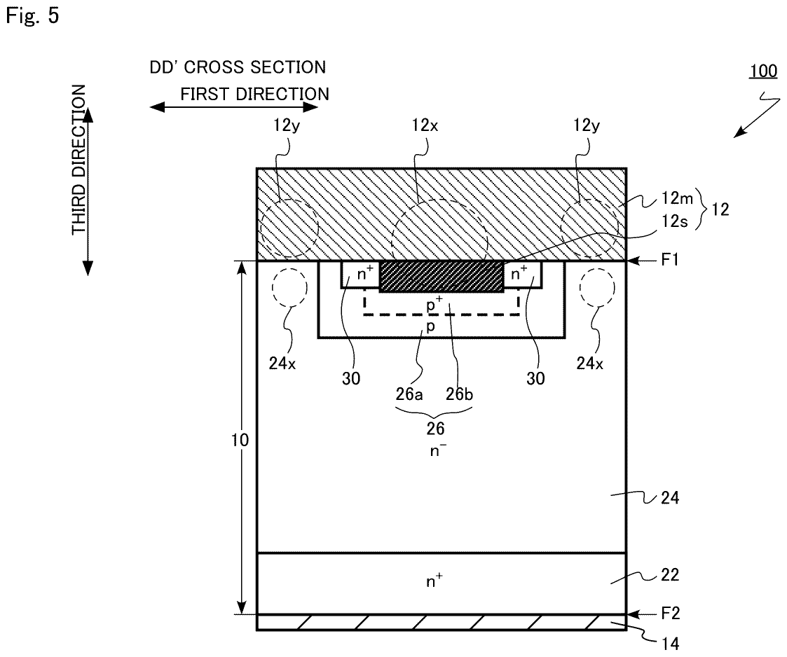

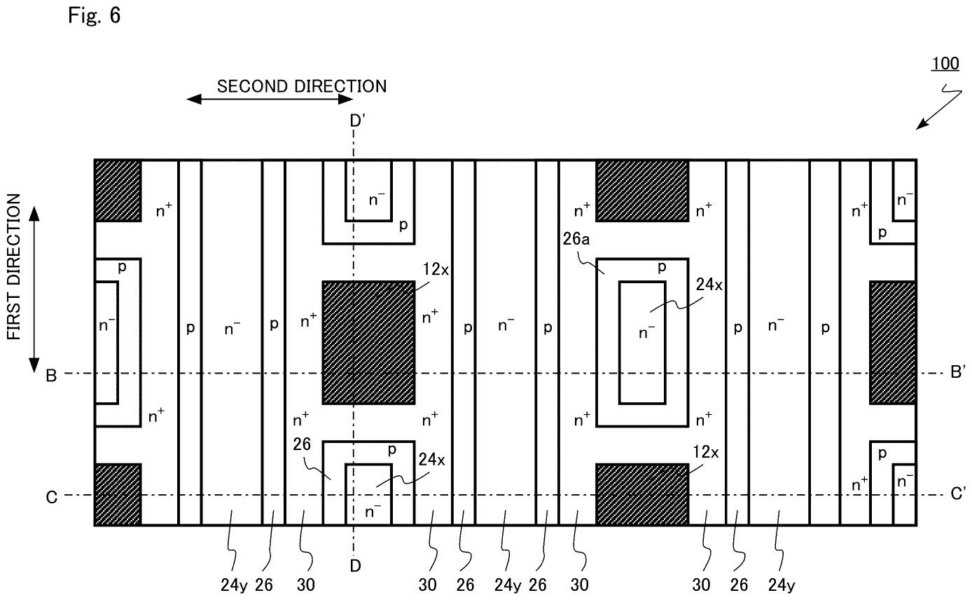

FIGS. 3, 4, and 5 are enlarged schematic cross-sectional views of the semiconductor device according to the first embodiment. FIG. 6 is an enlarged schematic top view of the semiconductor device according to the first embodiment. FIG. 6 is a diagram showing a pattern of a semiconductor region on the surface of a silicon carbide layer. FIG. 3 is a cross-sectional view taken along the line BB′ of FIG. 6. FIG. 4 is a cross-sectional view taken along the line CC′ of FIG. 6. FIG. 5 is a cross-sectional view taken along the line DD′ of FIG. 6.

The MOSFET 100 includes a silicon carbide layer 10, a source electrode 12 (first electrode), a drain electrode 14 (second electrode), a gate insulating layer 16, a gate electrode 18, and an interlayer insulating layer 20. The source electrode 12 includes a metal silicide layer 12s and a metal layer 12m. The source electrode 12 includes a contact electrode portion 12x (first portion) and a diode electrode portion 12y (second portion). The gate insulating layer 16 includes a first gate insulating layer 16a, a second gate insulating layer 16b, and a third gate insulating layer 16c. The gate electrode 18 include a first gate electrode 18a, a second gate electrode 18b, and a third gate electrode 18c.

An n⁺-type drain region 22, an n⁻-type drift region 24 (first silicon carbide region), a p-type body region 26 (second silicon carbide region), and an n⁺-type source region 30 (third silicon carbide region) are provided in the silicon carbide layer 10. The p-type body region 26 includes a p-type low concentration region 26a and a p⁺-type high concentration region 26b.

The drift region 24 includes a JBS region 24x (region) and a JFET region 24y. In addition, JBS is an abbreviation for Junction Barrier Schottky. In addition, JFET is an abbreviation for Junction Field Effect Transistor.

The silicon carbide layer 10 is provided between the source electrode 12 and the drain electrode 14. The silicon carbide layer 10 is a single crystal SiC. The silicon carbide layer 10 is, for example, 4H-SiC.

The silicon carbide layer 10 includes a first face (“F1” in FIG. 1) and a second face (“F2” in FIG. 1).

Hereinafter, the first face F1 may be referred to as a surface, and the second face F2 may be referred to as a back surface. The first face F1 is disposed on the source electrode 12 side of the silicon carbide layer 10. In addition, the second face F2 is disposed on the drain electrode 14 side of the silicon carbide layer 10. The first face F1 and the second face F2 face each other. Hereinafter, the “depth” means a depth in a direction toward the second face with the first face as a reference.

The first direction and the second direction are parallel to a first face F1. The second direction is perpendicular to the first direction.

The first face F1 is, for example, a face inclined by an angle equal to or more than 0° and equal to or less than 8° with respect to the (0001) face. In addition, the second face F2 is, for example, a face inclined by an angle equal to or more than 0° and equal to or less than 8° with respect to the (000-1) face. The (0001) face is referred to as a silicon face. The (000-1) face is referred to as a carbon face.

The n⁺-type drain region 22 is provided on the back surface side of the silicon carbide layer 10. the drain region 22 contains, for example, nitrogen (N) as an n-type impurity. The n-type impurity concentration of the drain region 22 is, for example, equal to or more than 1×10¹⁸ cm⁻³ and equal to or less than 1×10²¹ cm⁻³.

The n⁻-type drift region 24 is provided between the drain region 22 and the first face F1. The n⁻-type drift region 24 is provided between the source electrode 12 and the drain electrode 14. The n⁻-type drift region 24 is provided between the gate electrode 18 and the drain electrode 14.

The n⁻-type drift region 24 is provided on the drain region 22. The drift region 24 contains, for example, nitrogen (N) as an n-type impurity. The n-type impurity concentration of the drift region 24 is lower than the n-type impurity concentration of the drain region 22. The n-type impurity concentration of the drift region 24 is, for example, equal to or more than 4×10¹⁴ cm⁻³ and equal to or less than 5×10¹⁷ cm⁻³. The thickness of the drift region 24 is, for example, equal to or more than 3 μm and equal to or less than 150 μm.

The drift region 24 includes a JBS region 24x. The JBS region 24x is in contact with the first face F1. The JBS region 24x is surrounded by the body region 26.

The JBS region 24x is in contact with the diode electrode portion 12y of the source electrode 12. The JBS region 24x functions as a cathode region of the SBD.

The drift region 24 includes the JFET region 24y. The JFET region 24y is in contact with the first face F1. The JFET region 24y is interposed between two body regions 26 in the second direction.

The JFET region 24y faces the gate electrode 18. The JFET region 24y functions as an on-current path when the MOSFET 100 is in an on state.

The p-type body region 26 is provided between the drift region 24 and the first face F1. The body region 26 extends in the first direction. The body region 26 functions as a channel region of the MOSFET 100.

The body region 26 contains, for example, aluminum (Al) as a p-type impurity. The p-type impurity concentration of the body region 26 is, for example, equal to or more than 5×10¹⁶ cm⁻³ and equal to or less than 5×10²⁰ cm⁻³.

The depth of the body region 26 is, for example, equal to or more than 0.4 μm and equal to or less than 2 μm.

The body region 26 is in contact with the source electrode 12. The body region 26 is in contact with the contact electrode portion 12x of the source electrode 12. The body region 26 is electrically connected to the source electrode 12. The contact between the body region 26 and the source electrode 12 is, for example, an ohmic contact. The body region 26 is fixed to the electric potential of the source electrode 12.

A part of the body region 26 is in contact with the first face F1. A part of the body region 26 faces the gate electrode 18. A part of the body region 26 becomes a channel region of the MOSFET 100. The gate insulating layer 16 is interposed between a part of the body region 26 and the gate electrode 18.

The body region 26 includes the p-type low concentration region 26a and the p⁺-type high concentration region 26b.

A part of the low concentration region 26a is in contact with the first face F1. A part of the low concentration region 26a faces the gate electrode 18. A part of the low concentration region 26a becomes a channel region of the MOSFET 100. The gate insulating layer 16 is interposed between a part of the low concentration region 26a and the gate electrode 18.

The low concentration region 26a contains, for example, aluminum (Al) as a p-type impurity. The p-type impurity concentration of the low concentration region 26a is, for example, equal to or more than 5×10¹⁶ cm⁻³ and equal to or less than 5×10¹⁸ cm⁻³.

The high concentration region 26b is provided between the low concentration region 26a and the first face F1. The high concentration region 26b is in contact with the source electrode 12. The high concentration region 26b is in contact with the contact electrode portion 12x of the source electrode 12.

The p-type impurity concentration of the high concentration region 26b is higher than the p-type impurity concentration of the low concentration region 26a.

The high concentration region 26b contains, for example, aluminum (Al) as a p-type impurity. The p-type impurity concentration of the high concentration region 26b is, for example, equal to or more than 1×10¹⁹ cm⁻³ and equal to or less than 5×10²⁰ cm⁻³.

The depth of the high concentration region 260 is, for example, equal to or more than 0.2 μm and equal to or less than 0.7 μm.

The n⁺-type source region 30 is provided between the body region 26 and the first face F1.

The source region 30 contains, for example, phosphorus (P) or nitrogen (N) as an n-type impurity. The n-type impurity concentration of the source region 30 is higher than the n-type impurity concentration of the drift region 24.

The n-type impurity concentration of the source region 30 is, for example, equal to or more than 1×10¹⁹ cm⁻³ and equal to or less than 1×10²⁰ cm⁻³. The depth of the source region 30 is smaller than the depth of the body region 26. The depth of the source region 30 is, for example, equal to or more than 0.1 μm and equal to or less than 0.4 μm.

The source region 30 is in contact with the source electrode 12. The source region 30 is in contact with the contact electrode portion 12x of the source electrode 12. The source region 30 is electrically connected to the source electrode 12. The contact between the source region 30 and the source electrode 12 is, for example, an ohmic contact. The source region 30 is fixed to the electric potential of the source electrode 12.

The source region 30 is formed, for example, by performing ion implantation of n-type impurities multiple times at different acceleration energies.

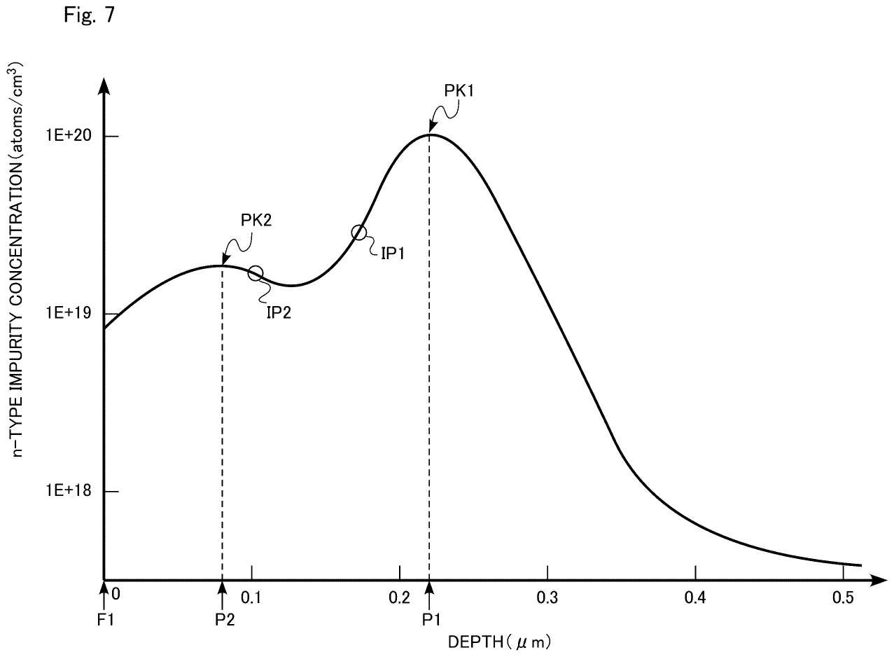

FIG. 7 is a diagram showing the impurity concentration distribution of the semiconductor device according to the first embodiment. FIG. 7 is a diagram showing the distribution of the n-type impurity concentration in the depth direction of the source region 30. In FIG. 7, the position of zero depth corresponds to the position of the first face F1. In FIG. 7, the n-type impurity concentration on the vertical axis is expressed on a logarithmic scale.

The distribution of the n-type impurity concentration of the source region 30 shows a maximum impurity concentration at the first position P1. The depth of the first position P1 indicating the maximum impurity concentration is, for example, equal to or more than 0.15 μm. The n-type impurity concentration at the first position P1 indicating the maximum impurity concentration is, for example, equal to or more than 3×10¹⁹ cm⁻³ and equal to or less than 1×10²⁰ cm⁻³.

The distribution of the n-type impurity concentration of the source region 30 has two inflection points on the first face F1 side of the first position P1. The two inflection points are a first inflection point IP1 and a second inflection point IP2. The position of the first inflection point IP1 is deeper than the position of the second inflection point IP2. The position of the first inflection point IP1 is closer to the first position P1 than the position of the second inflection point IP2.

The depth of the first inflection point IP1 is, for example, equal to or more than 0.15 μm.

The n-type impurity concentration at the first inflection point IP1 is, for example, higher than the n-type impurity concentration at the second inflection point IP2. The n-type impurity concentration at the first inflection point IP1 is, for example, equal to or more than 1.5 times and equal to or less than 10 times the n-type impurity concentration at the second inflection point IP2.

The depth of the second inflection point IP2 is, for example, equal to or less than 0.15 μm.

The n-type impurity concentration at the second inflection point IP2 is, for example, equal to or more than 1×10¹⁹ cm⁻³ and equal to or less than 3×10¹⁹ cm⁻³.

As shown in FIG. 7, the distribution of the n-type impurity concentration of the source region 30 has a first peak PK1 and a second peak PK2. The first peak PK1 is provided at the first position P1. The second peak PK2 is provided at the second position P2. The second position P2 is disposed between the first position P1 and the first face F1.

The depth of the first position P1 is, for example, equal to or more than 0.15 μm. In addition, the depth of the second position P2 is, for example, equal to or less than 0.1 μm.

The first conductive type impurity concentration at the second peak PK2 is lower than the n-type impurity concentration at the first peak PK1. The n-type impurity concentration at the first peak PK1 is, for example, equal to or more than 3×10¹⁹ cm⁻³ and equal to or less than 1×10²⁰ cm⁻³. In addition, the first conductive type impurity concentration at the second peak PK2 is, for example, equal to or more than 1×10¹⁹ cm⁻³ and equal to or less than 3×10¹⁹ cm⁻³.

In addition, the graph of the distribution of the n-type impurity concentration in the depth direction of the source region 30 shown in FIG. 7 can be obtained, for example, by fitting the logarithmic values of the measured values of the n-type impurity concentration in the depth direction of the source region 30 to a high-order function with the depth as a variable.

The gate electrode 18 is provided on the first face F1 side of the silicon carbide layer 10. The gate electrode 18 extends in the first direction. A plurality of gate electrodes 18 are arranged in parallel with each other in the second direction. The gate electrode 18 faces the JFET region 24y, the body region 26, and the source region 30 on the first face F1.

The first gate electrode 18a extends in the first direction. The first gate electrode 18a faces the JFET region 24y, the body region 26, and the source region 30 on the first face F1.

The second gate electrode 18b extends in the first direction. The second gate electrode 18b is provided in the second direction with respect to the first gate electrode 18a. The second gate electrode 18b faces the JFET region 24y, the body region 26, and the source region 30 on the first face F1.

The third gate electrode 18c extends in the first direction. The third gate electrode 18c is provided in the second direction with respect to the second gate electrode 18b. The second gate electrode 18b is provided between the first gate electrode 18a and the third gate electrode 18c. The third gate electrode 18c faces the JFET region 24y, the body region 26, and the source region 30 on the first face F1.

The gate electrode 18 is a conductive layer. The gate electrode 18 is, for example, polycrystalline silicon containing p-type impurities or n-type impurities.

The gate insulating layer 16 is provided between the gate electrode 18 and the JFET region 24y, the body region 26, and the source region 30. The first gate insulating layer 16a is provided between the first gate electrode 18a and the JFET region 24y, the body region 26, and the source region 30. The second gate insulating layer 16b is provided between the second gate electrode 18b and the JFET region 24y, the body region 26, and the source region 30. The third gate insulating layer 16c is provided between the third gate electrode 18c and the JFET region 24y, the body region 26, and the source region 30.

The gate insulating layer 16 contains, for example, silicon oxide. The gate insulating layer 16 includes, for example, a silicon oxide layer. For example, an insulating material with a high dielectric constant can be applied to the gate insulating layer 16. In addition, for example, a stacked structure of a silicon oxide layer and an insulating layer with a high dielectric constant can be applied to the gate insulating layer 16.

The thickness of the gate insulating layer 16 is, for example, equal to or more than 30 nm and equal to or less than 100 nm.

The interlayer insulating layer 20 is provided on the gate electrode 18. The interlayer insulating layer 20 is provided between the gate electrode 18 and the source electrode 12.

The interlayer insulating layer 20 electrically separates the gate electrode 18 and the source electrode 12 from each other. The interlayer insulating layer 20 contains, for example, silicon oxide. The interlayer insulating layer 20 is, for example, a silicon oxide layer.

The source electrode 12 is provided on the first face F1 side of the silicon carbide layer 10. The source electrode 12 is in contact with the silicon carbide layer 10. The source electrode 12 is in contact with the body region 26 and the source region 30.

The source electrode 12 includes the contact electrode portion 12x and the diode electrode portion 12y.

The contact electrode portion 12x is provided between the two gate electrodes 18. The contact electrode portion 12x is provided, for example, between the first gate electrode 18a and the second gate electrode 18b. The contact electrode portion 12x is in contact with the body region 26 and the source region 30.

For example, the interface between the contact electrode portion 12x and the body region 26 is disposed closer to the second face F2 than the first face F1 in a third direction perpendicular to the first face F1. For example, the contact electrode portion 12x is in contact with the source region 30 in the second direction.

The diode electrode portion 12y is provided between the two gate electrodes 18. For example, the diode electrode portion 12y is provided between the first gate electrode 18a and the second gate electrode 18b. The diode electrode portion 12y is provided in the first direction of the contact electrode portion 12x.

The contact electrode portion 12x and the diode electrode portion 12y are alternately and repeatedly arranged in the first direction between the same two gate electrodes 18.

The diode electrode portion 12y is in contact with the JBS region 24x of the drift region 24. The diode electrode portion 12y functions as an anode electrode of the SBD.

In the MOSFET 100, the diode electrode portion 12y and the contact electrode portion 12x are adjacent to each other in the second direction. The arrangement of the contact electrode portion 12x and the diode electrode portion 12y in the first direction is an arrangement shifted by a half cycle with respect to the arrangement of the contact electrode portion 12x and the diode electrode portion 12y in the first direction, which are adjacent to each other in the second direction.

In the MOSFET 100, the diode electrode portion 12y and the contact electrode portion 12x are arranged in a checkerboard pattern.

The source electrode 12 includes the metal silicide layer 12s and the metal layer 12m. The metal silicide layer 12s is provided between the silicon carbide layer 10 and the metal layer 12m.

The metal silicide layer 12s is in contact with the body region 26. The metal silicide layer 12s is in contact with the source region 30.

The metal silicide layer 12s contains, for example, nickel (Ni), titanium (Ti), or cobalt (Co). The metal silicide layer 12s is, for example, a nickel silicide layer, a titanium silicide layer, or a cobalt silicide layer.

The metal layer 12m contains metal. The metal layer 12m has, for example, a stacked structure of a barrier metal film and a metal film.

The barrier metal film contains, for example, titanium (Ti), tungsten (W), or tantalum (Ta). The barrier metal film is, for example, a titanium film, a titanium nitride film, a tungsten nitride film, or a tantalum nitride film.

The metal film contains, for example, aluminum (Al). The metal film is, for example, an aluminum film.

The contact electrode portion 12x includes the metal silicide layer 12s. Since the contact electrode portion 12x includes the metal silicide layer 12s, ohmic contact is formed between the source electrode 12 and the body region 26 and between the source electrode 12 and the source region 30.

The diode electrode portion 12y includes, for example, a barrier metal film.

For example, when the diode electrode portion 12y includes a barrier metal film, Schottky contact is formed between the source electrode 12 and the JBS region 24x.

The drain electrode 14 is provided on the second face F2 side of the silicon carbide layer 10. The drain electrode 14 is provided on the second face F2 of the silicon carbide layer 10. The drain electrode 14 is in contact with the second face F2.

The drain electrode 14 contains, for example, a metal or a metal semiconductor compound. The drain electrode 14 includes, for example, a nickel silicide layer, a titanium layer, a nickel layer, a silver layer, or a gold layer.

The drain electrode 14 is electrically connected to the drain region 22. The drain electrode 14 is in contact with, for example, the drain region 22.

Next, the function and effect of the MOSFET 100 according to the first embodiment will be described.

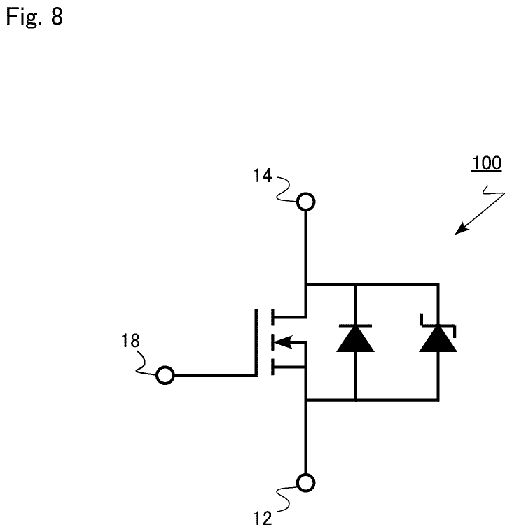

FIG. 8 is an equivalent circuit diagram of the semiconductor device according to the first embodiment. In the MOSFET 100, between the source electrode 12 and the drain electrode 14, a pn diode and an SBD are connected as built-in diodes in parallel with a transistor. The body region 26 is an anode region of the pn junction diode, and the drift region 24 is a cathode region of the pn junction diode. In addition, the source electrode 12 is an anode electrode of the SBD, and the JBS region 24x is a cathode region of the SBD.

For example, a case where the MOSFET 100 is used as a switching element connected to an inductive load is considered. When the MOSFET 100 is turned off, a voltage that is positive with respect to the drain electrode 14 may be applied to the source electrode 12 due to an induced current caused by an inductive load. In this case, a forward current flows through the built-in diode. This state is also referred to as a reverse conduction state.

If the MOSFET does not include an SBD, a forward current flows through the pn junction diode. The pn junction diode operates in a bipolar manner. When a freewheeling current is made to flow by using a pn junction diode that operates in a bipolar manner, a stacking fault grows in a silicon carbide layer due to the recombination energy of carriers. When the stacking fault grows in the silicon carbide layer, there arises a problem that the on-resistance of the MOSFET increases. The increase in the on-resistance of the MOSFET leads to a reduction in the reliability of the MOSFET.

The MOSFET 100 includes an SBD. A forward voltage (Vf) at which a forward current starts to flow through the SBD is lower than a forward voltage (Vf) of the pn junction diode. Therefore, a forward current flows through the SBD prior to the pn junction diode.

The forward voltage (Vf) of the SBD is, for example, equal to or more than 1.0 V and less than 2.0 V. The forward voltage (Vf) of the pn junction diode is, for example, equal to or more than 2.0 V and equal to or less than 3.0 V.

The SBD operates in a unipolar manner. Therefore, even if a forward current flows, the growth of a stacking fault in the silicon carbide layer 10 due to the recombination energy of carriers does not occur.

Therefore, an increase in the on-resistance of the MOSFET 100 is suppressed. As a result, the reliability of MOSFET 100 is improved.

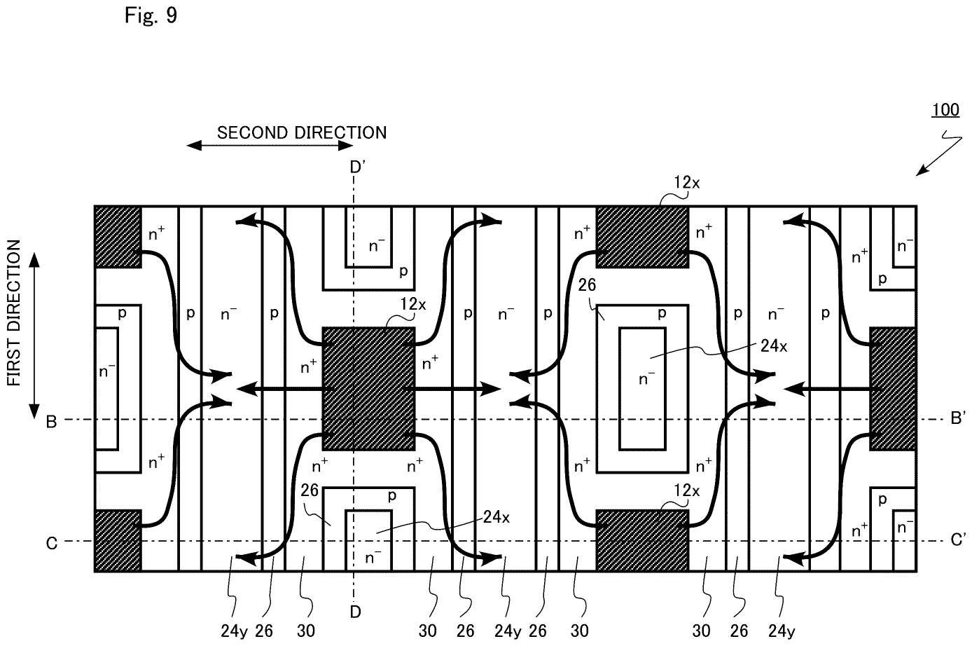

FIG. 9 is a diagram illustrating the problem of the semiconductor device according to the first embodiment. FIG. 9 is a diagram corresponding to FIG. 6 in the first embodiment.

FIG. 9 shows a current path for an on-current flowing in the vicinity of the first face F1 of the MOSFET 100 when the MOSFET 100 is in an on state. The current path for the on-current is indicated by an arrow.

As shown in FIG. 9, in the second direction, between the JBS region 24x and the JFET region 24y, there is no portion where the contact electrode portion 12x and the source region 30 are in contact with each other. Therefore, as shown in FIG. 9, an on-current flows from the contact electrode portion 12x through the source region 30 in the first direction, and then flows to the JFET region 24y through the body region 26 serving as a channel region.

As the electrical resistance of the source region 30 increases, the parasitic resistance of the MOSFET 100 increases, and the on-current of the MOSFET 100 decreases. In particular, as the distance between the contact electrode portions 12x adjacent to each other in the first direction increases, the path of a current flowing through the source region 30 in the first direction increases. Therefore, the increase in parasitic resistance becomes noticeable, and the reduction in the on-current of the MOSFET 100 becomes noticeable.

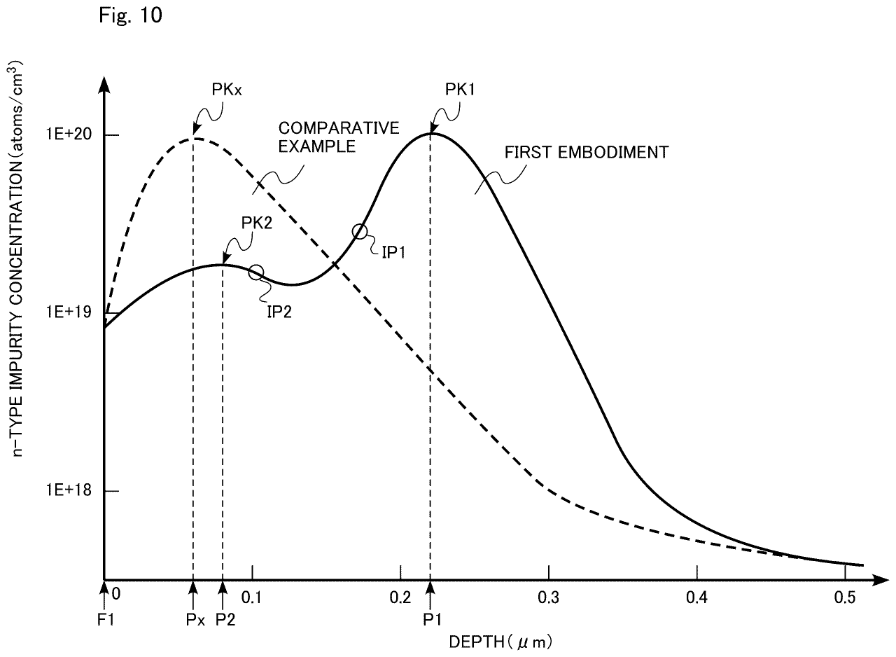

FIG. 10 is a diagram showing the impurity concentration distribution in a semiconductor device according to a comparative example. FIG. 10 is a diagram showing the distribution of the n-type impurity concentration in the depth direction of the source region 30. In FIG. 10, the position of zero depth corresponds to the position of the first face F1. In FIG. 10, the n-type impurity concentration on the vertical axis is expressed on a logarithmic scale.

In FIG. 10, the distribution of the n-type impurity concentration of the semiconductor device according to the comparative example is shown by a dotted line. In FIG. 10, the distribution of the n-type impurity concentration of the semiconductor device according to the first embodiment is shown by a solid line.

As shown in FIG. 10, the distribution of the n-type impurity concentration of the semiconductor device according to the comparative example has a peak Pkx at a position Px. The distribution of the n-type impurity concentration of the semiconductor device according to the comparative example shows a maximum impurity concentration at the position Px. The distribution of the n-type impurity concentration of the semiconductor device according to the comparative example does not have an inflection point on the first face F1 side of the position Px.

In the semiconductor device according to the comparative example, for example, if the n-type impurity concentration at the position Px is increased, the electrical resistance of the source region is reduced. Therefore, the parasitic resistance of the MOSFET is reduced to increase the on-current of the MOSFET.

However, if the n-type impurity concentration of the source region increases, the defect density in the source region increases. The defects in the source region are caused, for example, by the ion implantation of n-type impurities to form the source region.

In particular, when the n-type impurity concentration of the source region in contact with the gate insulating layer increases and accordingly the defect density increases, the reliability of the gate insulating layer on the source region decreases. When the defect density in the source region in the vicinity of the first face F1 increases, the reliability of the gate insulating layer on the source region decreases. Specifically, for example, the time-dependent dielectric breakdown (TDDB) characteristic of the gate insulating layer is degraded.

The distribution of the n-type impurity concentration of the MOSFET 100 according to the first embodiment has two inflection points on the first face F1 side of the first position P1 indicating the maximum impurity concentration. Since the distribution of the n-type impurity concentration has two inflection points, a low impurity concentration region with a predetermined width that has an n-type impurity concentration equal to or more than a predetermined concentration can be formed on the first face F1 side of the first position P1.

In the MOSFET 100 according to the first embodiment, the electrical resistance of the source region 30 is reduced by increasing the n-type impurity concentration at the first position P1. Therefore, the parasitic resistance of the MOSFET 100 is reduced to increase the on-current of the MOSFET 100.

In the MOSFET 100 according to the first embodiment, a low impurity concentration region with a predetermined width is provided on the first face F1 side of the first position P1. Therefore, the n-type impurity concentration of the source region 30 in contact with the gate insulating layer 16 is low, and the defect density is reduced. In other words, the defect density in the source region 30 in the vicinity of the first face F1 is reduced. Therefore, the reliability of the gate insulating layer on the source region 30 is improved.

In addition, since the low impurity concentration region provided in the MOSFET 100 according to the first embodiment has two inflection points, the low impurity concentration region has an n-type impurity concentration equal to or more than a predetermined concentration. In other words, in the low impurity concentration region, a predetermined level of n-type impurity concentration is maintained. Therefore, a decrease in the electrical resistance of the source region 30 in the vicinity of the first face F1 is suppressed. Therefore, the parasitic resistance of the MOSFET 100 is reduced to increase the on-current of the MOSFET 100.

According to the first embodiment, the source region 30 includes a low impurity concentration region with a predetermined width, which has an n-type impurity concentration equal to or more than a predetermined concentration, on the surface side of the position where the n-type impurity concentration is maximum, thereby realizing the MOSFET 100 that can achieve both an increase in on-current and an improvement in the reliability of the gate insulating layer.

From the viewpoint of increasing the on-current of the MOSFET 100, it is preferable that the maximum impurity concentration at the first position P1 is high. The n-type impurity concentration at the first position P1 is preferably equal to or more than 3×10¹⁹ cm⁻³, more preferably equal to or more than 5×10¹⁹ cm⁻³, and even more preferably equal to or more than 8×10¹⁹ cm⁻³.

From the viewpoint of increasing the on-current of the MOSFET 100, it is preferable that the n-type impurity concentration at the first inflection point IP1 is higher than the n-type impurity concentration at the second inflection point IP2.

From the viewpoint of increasing the on-current of the MOSFET 100, it is preferable that the n-type impurity concentration at the second inflection point IP2 is high. The n-type impurity concentration at the second inflection point IP2 is preferably equal to or more than 1×10¹⁹ cm⁻³, and more preferably equal to or more than 2×10¹⁹ cm⁻³.

From the viewpoint of increasing the on-current of the MOSFET 100, it is preferable that the depth of the second inflection point IP2 is small. The depth of the second inflection point IP2 is preferably equal to or less than 0.15 μm, and more preferably equal to or less than 0.1 μm.

From the viewpoint of improving the reliability of the gate insulating layer 16 of the MOSFET 100, it is preferable that the depth of the first position P1 indicating the maximum impurity concentration is large.

The depth of the first position P1 is preferably equal to or more than 0.15 μm, and more preferably equal to or more than 0.2 μm.

From the viewpoint of improving the reliability of the gate insulating layer 16 of the MOSFET 100, it is preferable that the depth of the first inflection point IP1 is large. The depth of the first inflection point IP1 is preferably equal to or more than 0.15 μm, and more preferably equal to or more than 0.2 μm.

From the viewpoint of improving the reliability of the gate insulating layer 16 of the MOSFET 100, it is preferable that the n-type impurity concentration at second inflection point IP2 is low. The n-type impurity concentration at the second inflection point IP2 is preferably equal to or less than 3×10¹⁹ cm⁻³, and more preferably equal to or less than 2×10¹⁹ cm⁻³.

From the viewpoint of achieving both an increase in the on-current of the MOSFET 100 and an improvement in the reliability of the gate insulating layer 16, the n-type impurity concentration at the first inflection point IP1 is preferably equal to or more than 1.5 times and equal to or less than 10 times the n-type impurity concentration at the second inflection point IP2, and more preferably equal to or more than twice and equal to or less than 5 times the n-type impurity concentration at the second inflection point IP2.

From the viewpoint of increasing the on-current of the MOSFET 100, it is preferable that the n-type impurity concentration at the first peak PK1 is high. The n-type impurity concentration at the first peak PK1 is preferably equal to or more than 3×10¹⁹ cm⁻³, more preferably equal to or more than 5×10¹⁹ cm⁻³, and even more preferably equal to or more than 8×10¹⁹ cm⁻³.

From the viewpoint of increasing the on-current of the MOSFET 100, it is preferable that the n-type impurity concentration at the second peak PK2 is high. The n-type impurity concentration at the second peak PK2 is preferably equal to or more than 1×10¹⁹ cm⁻³, and more preferably equal to or more than 2×10¹⁹ cm⁻³.

From the viewpoint of increasing the on-current of the MOSFET 100, it is preferable that the depth of the second peak PK2 is small. The depth of the second peak PK2 is preferably equal to or less than 0.1 μm, and more preferably equal to or less than 0.08 μm.

From the viewpoint of improving the reliability of the gate insulating layer 16 of the MOSFET 100, it is preferable that the depth of the first position P1 where the first peak PK1 is provided is large. The depth of the first position P1 is preferably equal to or more than 0.15 μm, and more preferably equal to or more than 0.2 μm.

From the viewpoint of improving the reliability of the gate insulating layer 16 of the MOSFET 100, it is preferable that the n-type impurity concentration at the second peak PK2 is low. The n-type impurity concentration at the second peak PK2 is preferably equal to or less than 3×10¹⁹ cm⁻³, and more preferably equal to or more than 2×10¹⁹ cm⁻³.

### Modification Example

A semiconductor device according to a modification example of the first embodiment is different from the semiconductor device according to the first embodiment in that the distribution of the first conductive type impurity concentration of the third silicon carbide region in a direction from the first face to the second face includes four inflection points and three peaks.

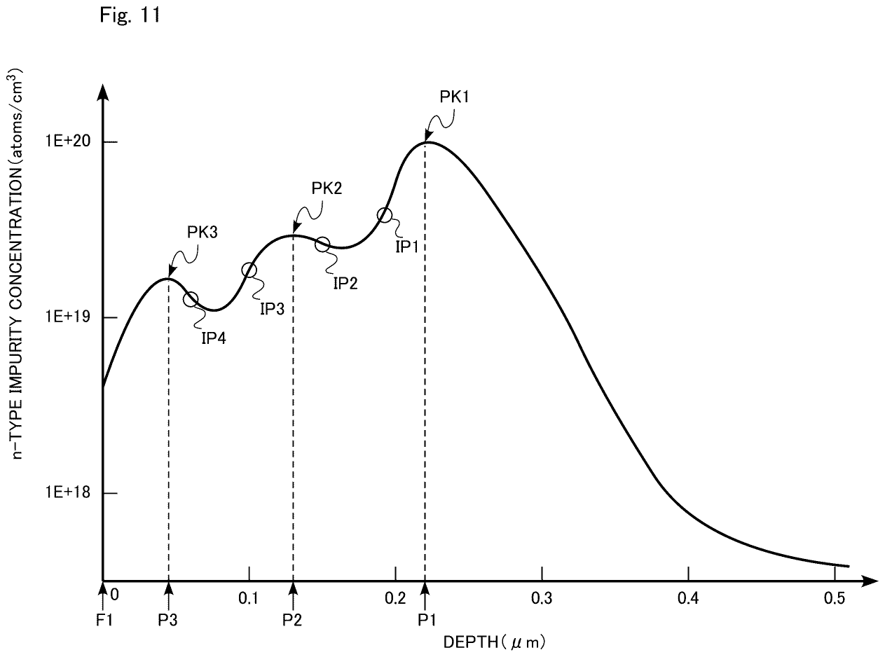

FIG. 11 is a diagram showing the impurity concentration distribution of the semiconductor device according to the modification example of the first embodiment. FIG. 11 is a diagram showing the distribution of the n-type impurity concentration in the depth direction of the source region 30. In FIG. 11, the position of zero depth corresponds to the position of the first face F1. In FIG. 11, the n-type impurity concentration on the vertical axis is expressed on a logarithmic scale.

The distribution of the n-type impurity concentration of the source region 30 shows a maximum impurity concentration at the first position P1. The depth of the first position P1 indicating the maximum impurity concentration is, for example, equal to or more than 0.15 μm. The n-type impurity concentration at the first position P1 indicating the maximum impurity concentration is, for example, equal to or more than 3×10¹⁹ cm⁻³ and equal to or less than 1×10²⁰ cm⁻³.

The distribution of the n-type impurity concentration of the source region 30 has four inflection points on the first face F1 side of the first position P1. The four inflection points are a first inflection point IP1, a second inflection point IP2, a third inflection point IP3, and a fourth inflection point IP4.

The position of the first inflection point IP1 is deeper than the position of the second inflection point IP2. The position of the second inflection point IP2 is deeper than the position of the third inflection point IP3. The position of the third inflection point IP3 is deeper than the position of the fourth inflection point IP4.

The position of the first inflection point IP1 is closest to the first position P1. The position of the fourth inflection point IP4 is closest to the first face F1.

The depth of the first inflection point IP1 is, for example, equal to or more than 0.15 μm.

The n-type impurity concentration at the first inflection point IP1 is higher than the n-type impurity concentrations at the second inflection point IP2, the third inflection point IP3, and the fourth inflection point IP4, for example. The n-type impurity concentration at the first inflection point IP1 is, for example, equal to or more than 1.5 times and equal to or less than 10 times the n-type impurity concentrations at the second inflection point IP2, the third inflection point IP3, and the fourth inflection point IP4.

The depth of the fourth inflection point IP4 is, for example, equal to or less than 0.15 μm.

The n-type impurity concentrations at the second inflection point IP2, the third inflection point IP3, and the fourth inflection point IP4 are, for example, equal to or more than 1×10¹⁹ cm⁻³ and equal to or less than 3×10¹⁹ cm⁻³.

As shown in FIG. 11, the distribution of the n-type impurity concentration of the source region 30 has a first peak PK1, a second peak PK2, and a third peak PK3. The first peak PK1 is provided at the first position P1. The second peak PK2 is provided at the second position P2. The third peak PK3 is provided at the third position P3.

The second position P2 is disposed between the first position P1 and the first face F1. The third position P3 is disposed between the second position P2 and the first face F1.

The third peak PK3 is a peak closest to the first face F1.

The depth of the first position P1 is, for example, equal to or more than 0.15 μm. In addition, the depth of the third position P3 is, for example, equal to or less than 0.1 μm.

The n-type impurity concentrations at the second peak PK2 and the third peak PK3 are lower than the n-type impurity concentration at the first peak PK1. The n-type impurity concentration at the first peak PK1 is equal to or more than 3×10¹⁹ cm⁻³and equal to or less than 1×10²⁰ cm⁻³. In addition, the n-type impurity concentrations at the second peak PK2 and the third peak PK3 are equal to or more than 1×10¹⁹ cm⁻³ and equal to or less than 3×10¹⁹ cm⁻³.

According to the modification example of the first embodiment, as in the first embodiment, the source region 30 includes a low impurity concentration region with a predetermined width, which has an n-type impurity concentration equal to or more than a predetermined concentration, on the surface side of the position where the n-type impurity concentration is maximum, thereby realizing a MOSFET that can achieve both an increase in on-current and an improvement in the reliability of the gate insulating layer.

From the viewpoint of increasing the on-current of the MOSFET according to the modification example, it is preferable that the maximum impurity concentration at the first position P1 is high. The n-type impurity concentration at the first position P1 is preferably equal to or more than 3×10¹⁹ cm⁻³, more preferably equal to or more than 5×10¹⁹ cm⁻³, and even more preferably equal to or more than 8×10¹⁹ cm⁻³.

From the viewpoint of increasing the on-current of the MOSFET according to the modification example, it is preferable that the n-type impurity concentration at the first inflection point IP1 is higher than the n-type impurity concentrations at the second inflection point IP2, the third inflection point IP3, and the fourth inflection point IP4.

From the viewpoint of increasing the on-current of the MOSFET according to the modification example, it is preferable that the n-type impurity concentrations at the second inflection point IP2, the third inflection point IP3, and the fourth inflection point IP4 are high. The n-type impurity concentrations at the second inflection point IP2, the third inflection point IP3, and the fourth inflection point IP4 are preferably equal to or more than 1×10¹⁹ cm⁻³, and more preferably equal to or more than 2×10¹⁹ cm⁻³.

From the viewpoint of increasing the on-current of the MOSFET according to the modification example, it is preferable that the depth of the fourth inflection point IP4 is small. The depth of the fourth inflection point IP4 is preferably equal to or less than 0.15 μm, and more preferably equal to or less than 0.1 μm.

From the viewpoint of improving the reliability of the gate insulating layer 16 of the MOSFET according to the modification example, it is preferable that the depth of the first position P1 indicating the maximum impurity concentration is large. The depth of the first position P1 is preferably equal to or more than 0.15 μm, and more preferably equal to or more than 0.2 μm.

From the viewpoint of improving the reliability of the gate insulating layer 16 of the MOSFET according to the modification example, it is preferable that the depth of the first inflection point IP1 is large. The depth of the first inflection point IP1 is preferably equal to or more than 0.15 μm, and more preferably equal to or more than 0.2 μm.

From the viewpoint of improving the reliability of the gate insulating layer 16 of the MOSFET according to the modification example, it is preferable that the n-type impurity concentrations at the second inflection point IP2, the third inflection point IP3, and the fourth inflection point IP4 are low. The n-type impurity concentrations at the second inflection point IP2, the third inflection point IP3, and the fourth inflection point IP4 are preferably equal to or less than 3×10¹⁹ cm⁻³, and more preferably equal to or less than 2×10¹⁹ cm⁻³.

From the viewpoint of achieving both an increase in the on-current of the MOSFET according to the modification example and an improvement in the reliability of the gate insulating layer 16, the n-type impurity concentration at the first inflection point IP1 is preferably equal to or more than 1.5 times and equal to or less than 10 times the n-type impurity concentrations at the second inflection point IP2, the third inflection point IP3, and the fourth inflection point IP4, and more preferably equal to or more

### Than Twice and Equal to or Less Than 5 Times the N-type

impurity concentrations at the second inflection point IP2, the third inflection point IP3, and the fourth inflection point IP4.

From the viewpoint of increasing the on-current of the MOSFET according to the modification example, it is preferable that the n-type impurity concentration at the first peak PK1 is high. The n-type impurity concentration at the first peak PK1 is preferably equal to or more than 3×10¹⁹ cm⁻³, more preferably equal to or more than 5×10¹⁹ cm⁻³, and even more preferably equal to or more than 8×10¹⁹ cm⁻³.

From the viewpoint of increasing the on-current of the MOSFET according to the modification example, it is preferable that the n-type impurity concentrations at the second peak PK2 and the third peak PK3 are high. The n-type impurity concentrations at the second peak PK2 and the third peak are preferably equal to or more than 1×1019 cm⁻³, and more preferably equal to or more than 2×1019 cm⁻³.

From the viewpoint of increasing the on-current of the MOSFET according to the modification example, it is preferable that the depth of the third peak PK3 is small. The depth of the third peak PK3 is preferably equal to or less than 0.1 μm, and more preferably equal to or less than 0.08 μm.

From the viewpoint of improving the reliability of the gate insulating layer 16 of the MOSFET according to the modification example, it is preferable that the depth of the first position P1 where the first peak PK1 is provided is large. The depth of the first position P1 is preferably equal to or more than 0.15 μm, and more preferably equal to or more than 0.2 μm.

From the viewpoint of improving the reliability of the gate insulating layer 16 of the MOSFET according to the modification example, it is preferable that the n-type impurity concentrations at the second peak PK2 and the third peak PK3 are low. The n-type impurity concentrations at the second peak PK2 and the third peak PK3 are preferably equal to or less than 3×10¹⁹ cm⁻³, and more preferably equal to or more than 2×10¹⁹ cm⁻³.

As described above, according to the first embodiment and its modification example, a MOSFET is realized that can achieve both an increase in on-current and an improvement in the reliability of the gate insulating layer.

### Second Embodiment

A semiconductor device according to a second embodiment is different from the semiconductor device according to the first embodiment in that the distribution of the first conductive type impurity concentration of the third silicon carbide region in a direction from the first face to the second face does not have a plurality of peaks. Hereinafter, the description of a part of the content overlapping the first embodiment may be omitted.

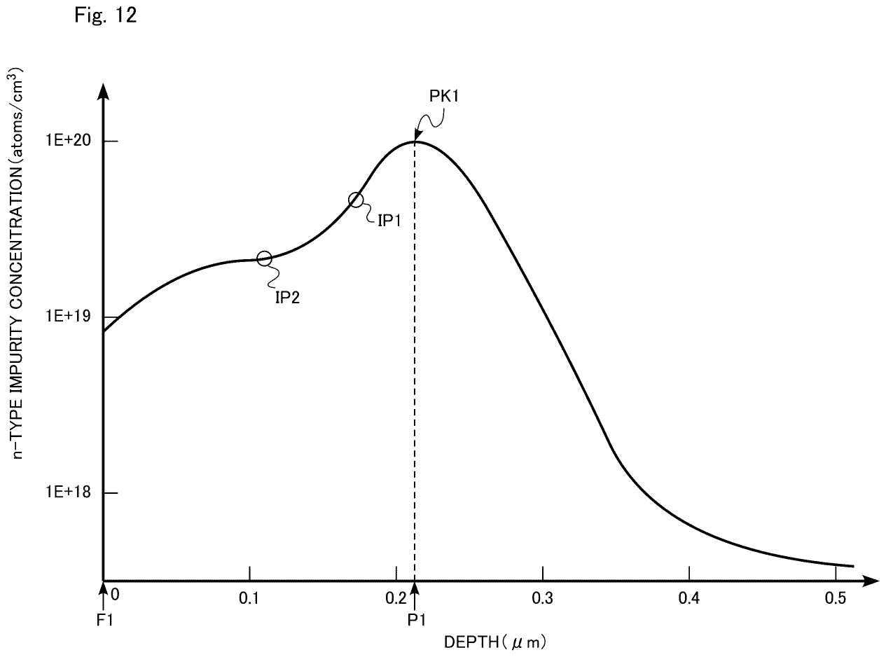

FIG. 12 is a diagram showing the impurity concentration distribution of the semiconductor device according to the second embodiment. FIG. 12 is a diagram showing the distribution of the n-type impurity concentration in the depth direction of the source region 30. In FIG. 12, the position of zero depth corresponds to the position of the first face F1. In FIG. 12, the n-type impurity concentration on the vertical axis is expressed on a logarithmic scale.

The distribution of the n-type impurity concentration of the source region 30 shows a maximum impurity concentration at the first position P1. The depth of the first position P1 indicating the maximum impurity concentration is, for example, equal to or more than 0.15 μm. The n-type impurity concentration at the first position P1 indicating the maximum impurity concentration is, for example, equal to or more than 3×10¹⁹ cm⁻³ and equal to or less than 1×10²⁰ cm⁻³.

The distribution of the n-type impurity concentration of the source region 30 has two inflection points on the first face F1 side of the first position P1. The two inflection points are a first inflection point IP1 and a second inflection point IP2. The position of the first inflection point IP1 is deeper than the position of the second inflection point IP2. The position of the first inflection point IP1 is closer to the first position P1 than the position of the second inflection point IP2.

The depth of the first inflection point IP1 is, for example, equal to or more than 0.15 μm.

The n-type impurity concentration at the first inflection point IP1 is, for example, higher than the n-type impurity concentration at the second inflection point IP2. The n-type impurity concentration at the first inflection point IP1 is, for example, equal to or more than 1.5 times and equal to or less than 10 times the n-type impurity concentration at the second inflection point IP2.

The depth of the second inflection point IP2 is, for example, equal to or less than 0.15 μm.

The n-type impurity concentration at the second inflection point IP2 is, for example, equal to or more than 1×10¹⁹ cm⁻³ and equal to or less than 3×10¹⁹ cm⁻³.

As shown in FIG. 12, the distribution of the n-type impurity concentration of the source region 30 has a first peak PK1. The first peak PK1 is provided at the first position P1. The depth of the first position P1 is, for example, equal to or more than 0.15 μm.

According to the second embodiment, as in the first embodiment, the source region 30 includes a low impurity concentration region with a predetermined width, which has an n-type impurity concentration equal to or more than a predetermined concentration, on the surface side of the position where the n-type impurity concentration is maximum, thereby realizing a MOSFET that can achieve both an increase in on-current and an improvement in the reliability of the gate insulating layer.

From the viewpoint of increasing the on-current of the MOSFET according to the second embodiment, it is preferable that the maximum impurity concentration at the first position P1 is high. The n-type impurity concentration at the first position P1 is preferably equal to or more than 3×10¹⁹ cm⁻³, more preferably equal to or more than 5×10¹⁹ cm⁻³, and even more preferably equal to or more than 8×10¹⁹ cm⁻³.

From the viewpoint of increasing the on-current of the MOSFET, it is preferable that the n-type impurity concentration at the first inflection point IP1 is higher than the n-type impurity concentration at the second inflection point IP2.

From the viewpoint of increasing the on-current of the MOSFET, it is preferable that the n-type impurity concentration at the second inflection point IP2 is high. The n-type impurity concentration at the second inflection point IP2 is preferably equal to or more than 1×10¹⁹ cm⁻³, and more preferably equal to or more than 2×10¹⁹ cm⁻³.

From the viewpoint of increasing the on-current of the MOSFET, it is preferable that the depth of the second inflection point IP2 is small. The depth of the second inflection point IP2 is preferably equal to or less than 0.15 μm, and more preferably equal to or less than 0.1 μm.

From the viewpoint of improving the reliability of the gate insulating layer 16 of the MOSFET, it is preferable that the depth of the first position P1 indicating the maximum impurity concentration is large. The depth of the first position P1 is preferably equal to or more than 0.15 μm, and more preferably equal to or more than 0.2 μm.

From the viewpoint of improving the reliability of the gate insulating layer 16 of the MOSFET, it is preferable that the depth of the first inflection point IP1 is large. The depth of the first inflection point IP1 is preferably equal to or more than 0.15 μm, and more preferably equal to or more than 0.2 μm.

From the viewpoint of improving the reliability of the gate insulating layer 16 of the MOSFET, it is preferable that the n-type impurity concentration at the second inflection point IP2 is low. The n-type impurity concentration at the second inflection point IP2 is preferably equal to or less than 3×10¹⁹ cm⁻³, and more preferably equal to or less than 2×10¹⁹ cm⁻³.

From the viewpoint of achieving both an increase in the on-current of the MOSFET and an improvement in the reliability of the gate insulating layer 16, the n-type impurity concentration at the first inflection point IP1 is preferably equal to or more than 1.5 times and equal to or less than 10 times the n-type impurity concentration at the second inflection point IP2, and more preferably equal to or more than 2 times and equal to or less than 5 times the n-type impurity concentration at the second inflection point IP2.

### Modification Example

A semiconductor device according to a modification example of the second embodiment is different from the semiconductor device according to the second embodiment in that the distribution of the first conductive type impurity concentration of the third silicon carbide region in a direction from the first face to the second face has four inflection points.

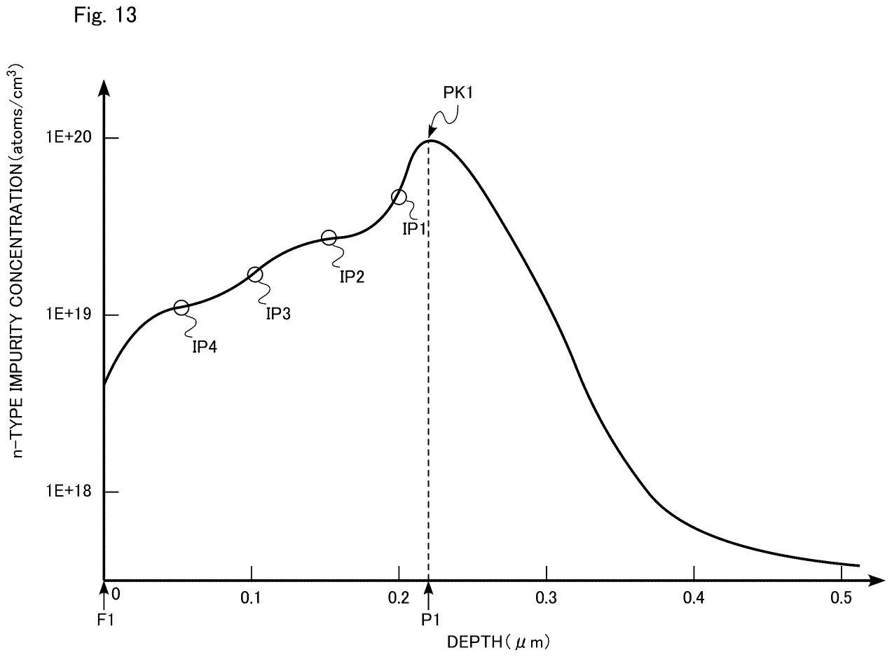

FIG. 13 is a diagram showing the impurity concentration distribution of the semiconductor device according to the modification example of the second embodiment. FIG. 13 is a diagram showing the distribution of the n-type impurity concentration in the depth direction of the source region 30. In FIG. 13, the position of zero depth corresponds to the position of the first face F1. In FIG. 13, the n-type impurity concentration on the vertical axis is expressed on a logarithmic scale.

The distribution of the n-type impurity concentration of the source region 30 shows a maximum impurity concentration at the first position P1. The depth of the first position P1 indicating the maximum impurity concentration is, for example, equal to or more than 0.15 μm. The n-type impurity concentration at the first position P1 indicating the maximum impurity concentration is, for example, equal to or more than 3×10¹⁹ cm⁻³ and equal to or less than 1×10²⁰ cm⁻³.

The distribution of the n-type impurity concentration of the source region 30 has four inflection points on the first face F1 side of the first position P1. The four inflection points are a first inflection point IP1, a second inflection point IP2, a third inflection point IP3, and a fourth inflection point IP4.

The position of the first inflection point IP1 is deeper than the position of the second inflection point IP2. The position of the second inflection point IP2 is deeper than the position of the third inflection point IP3. The position of the third inflection point IP3 is deeper than the position of the fourth inflection point IP4.

The position of the first inflection point IP1 is closest to the first position P1. The position of the fourth inflection point IP4 is closest to the first face F1.

The depth of the first inflection point IP1 is, for example, equal to or more than 0.15 μm.

The n-type impurity concentration at the first inflection point IP1 is higher than the n-type impurity concentrations at the second inflection point IP2, the third inflection point IP3, and the fourth inflection point IP4, for example. The n-type impurity concentration at the first inflection point IP1 is, for example, equal to or more than 1.5 times and equal to or less than 10 times the n-type impurity concentrations at the second inflection point IP2, the third inflection point IP3, and the fourth inflection point IP4.

The depth of the fourth inflection point IP4 is, for example, equal to or less than 0.15 μm.

The n-type impurity concentrations at the second inflection point IP2, the third inflection point IP3, and the fourth inflection point IP4 are, for example, equal to or more than 1×10¹⁹ cm⁻³ and equal to or less than 3×10¹⁹ cm⁻³.

According to the modification example of the second embodiment, as in the second embodiment, the source region 30 includes a low impurity concentration region with a predetermined width, which has an n-type impurity concentration equal to or more than a predetermined concentration, on the surface side of the position where the n-type impurity concentration is maximum, thereby realizing a MOSFET that can achieve both an increase in on-current and an improvement in the reliability of the gate insulating layer.

From the viewpoint of increasing the on-current of the MOSFET according to the modification example, it is preferable that the maximum impurity concentration at the first position P1 is high. The n-type impurity concentration at the first position P1 is preferably equal to or more than 3×10¹⁹ cm⁻³, more preferably equal to or more than 5×10¹⁹ cm⁻³, and even more preferably equal to or more than 8×10¹⁹ cm⁻³.

From the viewpoint of increasing the on-current of the MOSFET according to the modification example, it is preferable that the n-type impurity concentration at the first inflection point IP1 is higher than the n-type impurity concentrations at the second inflection point IP2, the third inflection point IP3, and the fourth inflection point IP4.

From the viewpoint of increasing the on-current of the MOSFET according to the modification example, it is preferable that the n-type impurity concentration at the second inflection point IP2 is high. The n-type impurity concentrations at the second inflection point IP2, the third inflection point IP3, and the fourth inflection point IP4 are preferably equal to or more than 1×10¹⁹ cm⁻³, and more preferably equal to or more than 2×10¹⁹ cm⁻³.

From the viewpoint of increasing the on-current of the MOSFET according to the modification example, it is preferable that the depth of the fourth inflection point IP4 is small. The depth of the fourth inflection point IP4 is preferably equal to or less than 0.15 μm, and more preferably equal to or less than 0.1 μm.

From the viewpoint of improving the reliability of the gate insulating layer 16 of the MOSFET according to the modification example, it is preferable that the depth of the first position P1 indicating the maximum impurity concentration is large. The depth of the first position P1 is preferably equal to or more than 0.15 μm, and more preferably equal to or more than 0.2 μm.

From the viewpoint of improving the reliability of the gate insulating layer 16 of the MOSFET according to the modification example, it is preferable that the depth of the first inflection point IP1 is large. The depth of the first inflection point IP1 is preferably equal to or more than 0.15 μm, and more preferably equal to or more than 0.2 μm.

From the viewpoint of improving the reliability of the gate insulating layer 16 of the MOSFET according to the modification example, it is preferable that the n-type impurity concentrations at the second inflection point IP2, the third inflection point IP3, and the fourth inflection point IP4 are low. The n-type impurity concentrations at the second inflection point IP2, the third inflection point IP3, and the fourth inflection point IP4 are preferably equal to or less than 3×10¹⁹ cm⁻³, and more preferably equal to or less than 2×10¹⁹ cm⁻³.

From the viewpoint of achieving both an increase in the on-current of the MOSFET according to the modification example and an improvement in the reliability of the gate insulating layer 16, the n-type impurity concentration at the first inflection point IP1 is preferably equal to or more than 1.5 times and equal to or less than 10 times the n-type impurity concentrations at the second inflection point IP2, the third inflection point IP3, and the fourth inflection point IP4, and more preferably equal to or more than twice and equal to or less than 5 times the n-type impurity concentrations at the second inflection point IP2, the third inflection point IP3, and the fourth inflection point IP4.

As described above, according to the second embodiment and its modification example, a MOSFET is realized that can achieve both an increase in on-current and an improvement in the reliability of the gate insulating layer.

In the first and second embodiments, the case where the number of inflection points is two or four has been described as an example. However, the number of inflection points is not particularly limited as long as the number of inflection points is equal to or more than two. In addition, in the first embodiment, the case where the number of peaks is two or three has been described as an example. However, the number of peaks is not particularly limited as long as the number of peaks is equal to or more than two.

In the first and second embodiments, the case of 4H-SiC has been described as an example of the crystal structure of SiC. However, the invention can also be applied to devices using SiC having other crystal structures, such as 6H-SiC and 3C-SiC. In addition, a face other than the (0001) face can also be applied as the surface of the silicon carbide layer 10.

In the first and second embodiments, the case where the first conductive type is n-type and the second conductive type is p-type has been described as an example. However, the first conductive type can be p-type and the second conductive type can be n-type.

In the first and second embodiments, aluminum (Al) has been exemplified as a p-type impurity, but boron (B) can also be used. In addition, although nitrogen (N) and phosphorus (P) have been exemplified as n-type impurities, arsenic (As), antimony (Sb), and the like can also be applied.

In addition, the invention can also be applied to an insulated gate bipolar transistor (IGBT).

While several embodiments of the invention have been described, these embodiments are presented as examples, and it is not intended to limit the scope of the invention. These novel embodiments can be implemented in various other forms, and various omissions, replacements, and modifications can be made without departing from the spirit of the invention. For example, a component in one embodiment may be replaced with or changed to a component in another embodiment. These embodiments or their modifications are included in the scope or gist of the invention, and are included in the scope of the inventions described in the claims and their equivalents.

### EXPLANATIONS OF LETTERS OR NUMERALS

10 SILICON CARBIDE LAYER
12 SOURCE ELECTRODE (FIRST ELECTRODE)
12x CONTACT ELECTRODE PORTION (FIRST PORTION)
12y DIODE ELECTRODE PORTION (SECOND PORTION)
14 DRAIN ELECTRODE (SECOND ELECTRODE)
16a FIRST GATE INSULATING LAYER
16b SECOND GATE INSULATING LAYER
18a FIRST GATE ELECTRODE
18b SECOND GATE ELECTRODE
24 DRIFT REGION (FIRST SILICON CARBIDE REGION)
24x JBS REGION (REGION)
26 BODY REGION (SECOND SILICON CARBIDE REGION)
30 SOURCE REGION (THIRD SILICON CARBIDE REGION)
100 MOSFET (SEMICONDUCTOR DEVICE)
F1 FIRST FACE
F2 SECOND FACE
IP1 FIRST INFLECTION POINT
P1 FIRST POSITION
PK1 FIRST PEAK

1. A semiconductor device, comprising:
a silicon carbide layer having a first face and a second face opposite to the first face and including:
a first silicon carbide region of a first conductive type having a region in contact with the first face;
a second silicon carbide region of a second conductive type provided between the first silicon carbide region and the first face and extending in a first direction parallel to the first face; and
a third silicon carbide region of the first conductive type provided between the second silicon carbide region and the first face, extending in the first direction, and having a first conductive type impurity concentration higher than a first conductive type impurity concentration in the first silicon carbide region;
a first gate electrode extending in the first direction and facing the second silicon carbide region and the third silicon carbide region;
a second gate electrode extending in the first direction, provided in a second direction perpendicular to the first direction with respect to the first gate electrode, and facing the second silicon carbide region and the third silicon carbide region;
a first gate insulating layer provided between the second silicon carbide region and the third silicon carbide region and the first gate electrode;
a second gate insulating layer provided between the second silicon carbide region and the third silicon carbide region and the second gate electrode;
a first electrode provided on a side of the first face of the silicon carbide layer and including:
a first portion provided between the first gate electrode and the second gate electrode and in contact with the second silicon carbide region and the third silicon carbide region; and
a second portion provided between the first gate electrode and the second gate electrode, provided in the first direction of the first portion, and in contact with the region of the first silicon carbide region; and
a second electrode provided on a side of the second face of the silicon carbide layer,
wherein a distribution of a first conductive type impurity concentration of the third silicon carbide region in a direction from the first face to the second face has a plurality of inflection points on the first face side of a first position where the distribution indicates a maximum impurity concentration when the first conductive type impurity concentration is expressed on a logarithmic scale.

2. The semiconductor device according to claim 1,
wherein a first conductive type impurity concentration at a first inflection point closest to the first position among the plurality of inflection points is higher than first conductive type impurity concentrations at other inflection points.

3. The semiconductor device according to claim 2,
wherein the first conductive type impurity concentration at the first inflection point is equal to or more than 1.5 times and equal to or less than 10 times the first conductive type impurity concentration at the other inflection points.

4. The semiconductor device according to claim 1,
wherein a depth of the first position is equal to or more than 0.15 μm.

5. The semiconductor device according to claim 1,
wherein a depth of a first inflection point closest to the first position among the plurality of inflection points is equal to or more than 0.15 μm.

6. The semiconductor device according to claim 1,
wherein the maximum impurity concentration is equal to or more than 3×10¹⁹ cm⁻³.

7. The semiconductor device according to claim 1,
wherein a depth of an inflection point closest to the first face among the plurality of inflection points is equal to or less than 0.15 μm.

8. The semiconductor device according to claim 1,
wherein an n-type impurity concentration at an inflection point other than a first inflection point closest to the first position among the plurality of inflection points is equal to or more than 1×10¹⁹ cm⁻³ and equal to or less than 3×10¹⁹ cm⁻³.

9. The semiconductor device according to claim 1,
wherein the distribution has a plurality of peaks including a first peak, and
the first peak is provided at the first position.

10. The semiconductor device according to claim 9,
wherein a depth of the first position is equal to or more than 0.15 μm, and
a depth of a position where a peak closest to the first face among the plurality of peaks is provided is equal to or less than 0.1 μm.

11. The semiconductor device according to claim 9,
wherein a first conductive type impurity concentration at the first peak is equal to or more than 3×10¹⁹ cm⁻³ and equal to or less than 1×10²⁰ cm⁻³, and
a first conductive type impurity concentration at a peak other than the first peak among the plurality of peaks is equal to or more than 1×10¹⁹ cm⁻³ and equal to or less than 3×10¹⁹ cm⁻³.

12. The semiconductor device according to claim 1,
wherein a depth of the third silicon carbide region is equal to or less than 0.4 μm.
